(19) United States
(12) Patent Application Publication
(10) Pub. No.: US 2004/0159538 A1
(43) Pub. Date: Aug. 19, 2004

(54) Photo mask blank, photo mask, method and apparatus for manufacturing of a photo mask blank

(76) Inventors: Hans Becker, Meiningen (DE); Mario Schiffler, Oepfershausen (DE); Frank Lenzen, Meiningen (DE); Ute Buttgereit, Zella-Mehlis (DE); Gunter Hess, Meiningen (DE)

Correspondence Address: M. Robert Kestenbaum, 11011 Bermuda Dunes NE, Albuquerque, NM, 87111, US

(21) Appl. No.: 10/367,539

(22) Filed: Feb. 13, 2003

(51) Int. Cl. C23C 14/32

(52) U.S. Cl. 204/192.11; 204/298.04

(57) ABSTRACT

The invention relates to a photo mask blank, a photo mask, a method and an apparatus for manufacturing of a photo mask blank in general and for manufacturing of a photo mask blank by particle beam sputtering in particular.

It is an object of the invention to provide a method of manufacturing a photo mask blank of high quality and high stability which is suitable for the production of a photo mask having small structures.

The invention proposes a method for manufacturing of a photo mask blank, wherein a substrate and a target are provided in a vacuum chamber. Said target is sputtered by irradiating with a first particle or ion beam and at least a first layer of a first material is deposited on said substrate by said sputtering of said target.

### FIELD OF THE INVENTION

The invention relates to a photo mask blank, a photo mask, a method and an apparatus for manufacturing of a photo mask blank in general and for manufacturing of a photo mask blank by particle beam sputtering in particular.

### BACKGROUND OF THE INVENTION

For manufacturing of integrated circuits, structures are typically produced on a silicon wafer by electron beam or photo lithography using a photo mask as an overlay for the structures of the integrated circuit.

Furthermore, the photo mask itself is also manufactured by a lithography process from a non-structured photo mask blank.

A photo mask blank typically comprises a transparent substrate on which a layer structure of one or more layers of shading, light absorbing or reflecting films is deposited.

Due to the ever-increasing demand of smaller structures and higher structure density in semi-conductor production the tolerable defect density and defect size on the wafer decreases. Therefore, also the quality demands for photo masks and, consequently for photo mask blanks, in particular regarding the number and size of defects, are increasing.

Photo masks and the respective photo masks blanks may be subdivided in three groups, namely binary, phase shifting and extreme ultra violet (EUV) photo masks or photo mask blanks, respectively.

The simplest type of photo mask is a binary photo mask which is exemplary discussed in the following.

A binary photo mask is adapted to be used in transparent projection mode. Typically, a binary photo mask and a respective binary photo mask blank comprise a first layer or film of an opaque or non-transmitting material, e.g. chrome or a chrome compound provided on a transparent substrate. A binary photo mask blank further comprises a second or top layer or film of an anti-reflective material, e.g. chrome oxide, on top of the opaque layer.

A more sophisticated type of photo mask is a so-called phase shifting photo mask. With a phase shifting photo mask destructive interference at structure edges is used to achieve a higher resolution to enable an increase of the structure density of the integrated circuit. With a phase shifting photo mask even structures below the projection wave length are achievable.

Phase shifting photo masks may again be subdivided in alternating phase shift masks and embedded attenuated phase shift masks. An alternating phase shift mask is typically used for regular structures like lines and spaces, wherein an embedded attenuated phase shift mask is typically used for producing single holes or dots or other single structures on the wafer.

An embedded attenuated phase shift mask comprises a transparent substrate and a structured phase shifting layer on top of the substrate. The structured phase shifting layer comprises transparent and semi-transparent portions. Light can pass through the transparent portions with an intensity which is enough to expose photo sensitive resist on the wafer. Transmission of the semi-transparent portions is typically between 5% and 20%, such that the light passing through these portions is not able to expose the photo sensitive resist. However, the phase of the light passing through the semi-transparent portions is shifted by about 180° with respect to the light passing through the transparent portions. At the edges of the structures a destructive interference is created. Therefore, contrast of the image on the wafer is enhanced. The phase shifting layers are modelled either as single layers or as multiple layer structures. Single layers typically comprise chrome compounds or metal silicide layers. Multiple layer structures typically comprise alternating layers of optically transparent and optically absorbing material.

For the production of those phase shifting layers reactive sputtering is a known method. For reactive sputtering a target is sputtered and the target material is deposited on a transparent substrate in a vacuum chamber under the presence of reactive gases.

Reactive sputtering provides a high productivity due to a high rate of deposition of the layers. A disadvantage of the high deposition rate is an increased creation of impurities, e.g. particle, liquid or gas inclusion, disadvantageously lowering the yield. On the other hand decreasing the deposition rate may result in the creation of large crystal grains which leading to a large film stress bending the photo mask blank and the photo mask. Film stress is disadvantageous as the positioning precision of the structures suffers which might even result in a complete uselessness of a photo mask produced by such a photo mask blank, in particular with critical structures such as wiring design of an integrated circuit.

It is known from EP-A-1 022 614 that the crystal grain size of a CrC-film can be reduced to between 3 nm and 7 nm by providing a sputter gas containing helium.

However, reactive sputtering still provides a relatively high yield of defective photo mask blanks, and is, therefore, still disadvantageous, in particular for high precision demands.

### SUMMARY OF THE INVENTION

Consequently, it is an object of the present invention to provide a method of manufacturing a photo mask blank of high quality and high stability which is suitable for the production of a photo mask having small structures.

A further object of the invention is to provide a method of manufacturing photo mask blanks with high reproducibility and with high yield.

Still a further object of the invention is to provide a variable method of manufacturing photo mask blanks.

Still a further object of the invention is to provide a method of manufacturing photo mask blanks with high precision having films with a low defect density and/or high adhesion at the substrate or at each other.

Still a further object of the invention is to provide photo mask blanks and photo masks of high quality, in particular regarding reflectance, optical density, etching time for the opaque layer, homogeneity of the layer thicknesses and having a low film stress.

Still a further object of the invention is to provide high quality photo mask blanks which are suitable for manufacturing of binary, phase shifting and EUV photo mask blanks.

Still a further object of the invention is to provide an apparatus to carry out the inventive method.

The object of the invention is achieved in a surprisingly simple manner the by subject matter of the claims.

A powerful alternative to reactive sputtering, in particular with respect to the ever-increasing quality and precision demands, is sputtering with a first particle beam. Preferably, said first particle beam comprises or is a first ion beam. In this preferred case, said first film is deposited by ion beam sputtering (IBS). Ion beam sputtering or ion beam deposition (IBD) enables to achieve high quality photo mask blanks of all types.

According to the invention, a photo mask blank, in particular a binary photo mask blank, a phase shifting photo mask blank or an extreme ultra violet photo mask blank is manufactured by providing a substrate and a target in a vacuum chamber, providing a first particle beam in the vacuum chamber and emitted from a first particle source or deposition source, sputtering said target by irradiating with said first particle beam and depositing at least a first layer of a first material on said substrate by said sputtering of said target.

With ion beam sputtering the first ion beam is directed onto the target. Thereby material or particles, e.g. atoms or molecules being sputtered from the target emerge from said target in direction to said substrate and are growing a layer or film on the substrate or on another layer or film already existing on the substrate.

Films produced by ion beam sputtering or ion beam deposition (IBD) are-highly stable due to a high deposition energy, caused by the momentum transfer in the sputtering process. The deposition energy is preferably >1 eV, >10 eV, >100 eV or >500 eV. Furthermore, ion beam deposition provides a high reproducibility.

However, according to the ever-increasing demand for providing smaller and smaller structures on a photo mask, the illumination wave lengths used for micro-lithography tend to shorter UV laser wave lengths and, therewith, the quality demands for photo mask blanks still increase considerably.

In this respect, a low defect density is an important parameter of a photo mask blank. Defects can be caused by the manufacturing process of the photo mask blank, in particular by particles, liquids or gases. Such defects may disadvatageously cause a loss of adhesion of the layers, either locally or over the whole photo mask blank. As a photo mask blank will be exposed, developed, etched, removed from resist and undergoes a plurality of cleaning steps, a location with low adhesion may cause a defect of the photo mask.

However, further important parameters for a photo mask blank, in particular regarding the optical quality exist. Those are for example reflectance, optical density, the etching time for the opaque layer, homogeneity of the layer thicknesses and a low film stress.

Preferably, the photo mask blank is directly irradiated by a second particle beam emitted by a second particle source or assist source, which is different from the deposition source. In, particular, the second particle beam is directed onto said photo mask blank, i.e. directly onto the substrate or directly onto one of said films deposited on the substrate. The second ion beam is preferably an ion beam too. However, for some applications it could also be an electron beam.

Preferably, irradiating said photo mask blank comprises irradiating said substrate and/or said first film and/or further deposited films before and/or after said step of depositing said film or films. Advantageously irradiating said photo mask blank by said second particle beam provides a large variety of treatment possibilities to improve the quality and performance of the photo mask blank. The invention particularly provides a photo mask blank with low particle contamination which is advantageous for all kinds of photo mask blanks.

The present invention is particularly well suited for manufacturing of binary photo mask blanks, phase shifting photo mask blanks and EUV photo mask blanks.

Preferably a second, a third and even further layers or films are disposed on said photo mask blank, in particular subsequently on each other. For a binary photo mask the first and second films preferably comprise or consist of a chrome compound, in particular the first film comprises CrN and the second film CrC. Furthermore the third or the last film is preferably an anti-reflective film, e.g. comprising CrON.

The present invention advantageously provides one or more, particularly different layers or films of high mass density providing a high optical density with relatively thin films. This improves the critical dimension (CD) value of the photo mask produced by the photo mask blank.

Preferably, the target and/or the substrate are mounted rotably or pivotably. By this, the system is adjustable to hit the target under an angle >0°, particularly >10 ° with respect to a target normal line by the first particle beam. Further preferably, the substrate defines a substrate normal line and sputtered particles from the sputter target and/or said second particle beam hit said photo mask blank, i.e. the substrate or a further film under an angle >0°, particularly >10 ° to the substrate normal line.

Advantageously, the invention provides a photo mask blank with a very low value of film stress of about 0.2 MPa or even less.

A further advantage of the present invention is that photo mask blanks are provided with an excellent adhesion of the first film on the substrate and/or of films on each other. Furthermore, the inventive method is advantageously highly reproducible, such that a high stability of the optical specifications both inter and intra plate are achieved.

The invention allows separate control of preferably all parameters involved in the deposition process. Preferably a gas is used to produce the ions of the first ion beam. The ions of the first ion beam preferably are or comprise rare gas ions, e.g. argon or xenon, because of their different momentum transfer function.

According to a preferred embodiment of the invention, a three grid ion extraction grid together with controllable radio frequency power plasma heating provides a separate adjustment of energy and current of the extracted ions within the construction limits. An extraction optical system provides accelerating, directing and/or focusing of the first particle or ion beam on its way to said target.

Preferably the distribution of the sputtered target atoms is adjustable by regulating parameters of the first particle beam, e.g. the incident angle, energy, current and/or mass of the particles or ions. By adjusting or controlling said parameters of the first particle beam, purity, chemical composition, surface condition and/or micro grain size of the target material are adjustable or controllable.

Furthermore the geometrical orientation of the substrate relative to the target, in particular the angle of incidence of the sputtered target atoms is adjustable. Adjusting these parameters the fundamental film growth can be influenced to optimize for stress, homogeneity and optical parameters.

Preferably the assist source and the deposition source are different sources, but are equivalently and/or independently adjustable. By this, the first and second particle beams are separately controllable and/or comprise different particles and/or have different particle energies.

Preferably, a deposition rate of >0.01 nm/sec or >0.05 nm/sec and/or <5 nm/sec, <2 nm/sec, <0.5 nm/sec or <0.3 nm/sec, most preferably in the range of about 0.1 nm/sec ±50% is provided. At first sight this might appear uneconomic, but on the other hand the low deposition rate allows a very precise control of film thickness both by time and in situ control. In particular for phase shifting and EUV photo mask blanks this is advantageous, as a very precise control of film- or period thickness is provided such that the required phase angle and a high reflectivity are achieved. Furthermore a homogeneity of the peak reflection of smaller than ±1% and a homogeneity of the center wavelength of smaller than ±0.1 nm over the whole area of the photo mask blank is achieved.

According to a preferred embodiment of the invention, the substrate is conditioned by irradiating the second particle beam before the first film is deposited. In this case a low energy ion beam, e.g. <100 eV or <30 eV is utilized as second particle beam. The energy of the second ion beam is adjusted to a value at which the substrate surface is not damaged by sputtering, but organic impurities, present at the surface, are cracked. Particularly, the energy of the ions of the second particle beam, is higher than the chemical binding energies of the impurities. Preferably, this physical cleaning effect is chemically intensified by providing one or more reactive gases present in the vacuum chamber, for example oxygen, at least for some time during the treatment. Advantageously, the adhesion of the first film on the substrate and/or the films on each other and the defect density are improved.

Alternatively or additionally to said conditioning of the surface, one or more of the films are doped by the second particle beam. Preferably a doping material which is available in gaseous form is used. According to the requirements that gas is used in its original state, ionized by the plasma inside the source or even accelerated towards the photo mask blank. Particularly in this case, the geometry and/or the incidence angle of the second particle beam are adjustable and/or controllable.

Preferably, one or more of the films are doped independently, which is possible by the invention, even when they are sputtered from the same target. So for example two films of the same target material are deposited and either only one film is doped or both films are independently doped, e.g. with different doping materials or doping parameters.

In a preferred embodiment, the last or top layer of a chrome binary mask is optimized for reflection by doping while one or more other films are differently doped, e.g. to adjust and optimize the optical density, the etch time, the adhesion, the reflectance and/or other features. E.g. the reflection of an anti-reflective coating can be decreased.

On the other hand, the reflectance of one or more reflecting layers of a EUV photo mask blank can be increased and/or homogenized by the treatment with the second particle beam.

In a further preferred embodiment, the substrate and/or one, several or all of the films are flattened or smoothened by irradiating with said second particle beam. Preferably a step of irradiating the photo mask blank by said second particle beam is carried out after one or more films are deposited. Flattening or smoothening one or more of the films is particularly advantageous for EUV photo mask blanks as EUV reflectance significantly depend on the interface roughness of the multi-layer stack which is, in particular reduced by the invention.

The invention is described in more detail and in view of preferred embodiments hereinafter. Reference is made to the attached drawings, wherein same and similar elements are denoted with the same reference signs.

### BRIEF DESCRIPTION OF THE FIGURES

It is shown in:

FIG. 1 a schematic setup of an apparatus according to the invention;

FIG. 2 a schematic cross section of an EUV photo mask blank (example 1);

FIG. 3a to 3c results of reflection measurements of the photo mask blank according to example 1;

FIG. 4 a transmission electron microscope image of a cross section of the photo mask blank according to example 1;

FIG. 5 surface images of a stack of 10 bi-layers (left column) and of 40 bi-layers (right column);

FIG. 6 results of reflection measurements of two EUV photo mask blanks with 30 and 50 bi-layers, respectively;

FIG. 7 a schematic cross section of a binary photo mask blank (example 2);

FIG. 8 results of a measurement of the optical density as a function of the wavelength of the binary photo mask blank according to example 2;

FIG. 9 results of a measurement of the reflection as a function of the wavelength of the binary photo mask blank according to example 2;

FIG. 10 results of a reflection measurement in a two-dimensional contour plot of the binary photo mask blank according to example 2;

FIG. 11a a schematic cross section of a composite phase shifting photo mask blank (example 3);

FIG. 11b a schematic cross section of a bi-layer phase shifting photo mask blank (example 4);

FIG. 11c a schematic cross section of a multi-layer phase shifting photo mask blank (example 5);

FIG. 12 results of a calculation of phase and transmission as a function of film thickness of a mono-layer phase shifting photo mask blank;

FIG. 13 results of a calculation of phase and transmission as a function of film thickness of a bi-layer phase shifting photo mask blank;

FIG. 14a results of a measurement of the wave length dispersion of SiO2; and

FIG. 14b results of a measurement of the wave length dispersion of SiN.

### DETAILED DESCRIPTION OF THE INVENTION

### The Deposition Apparatus

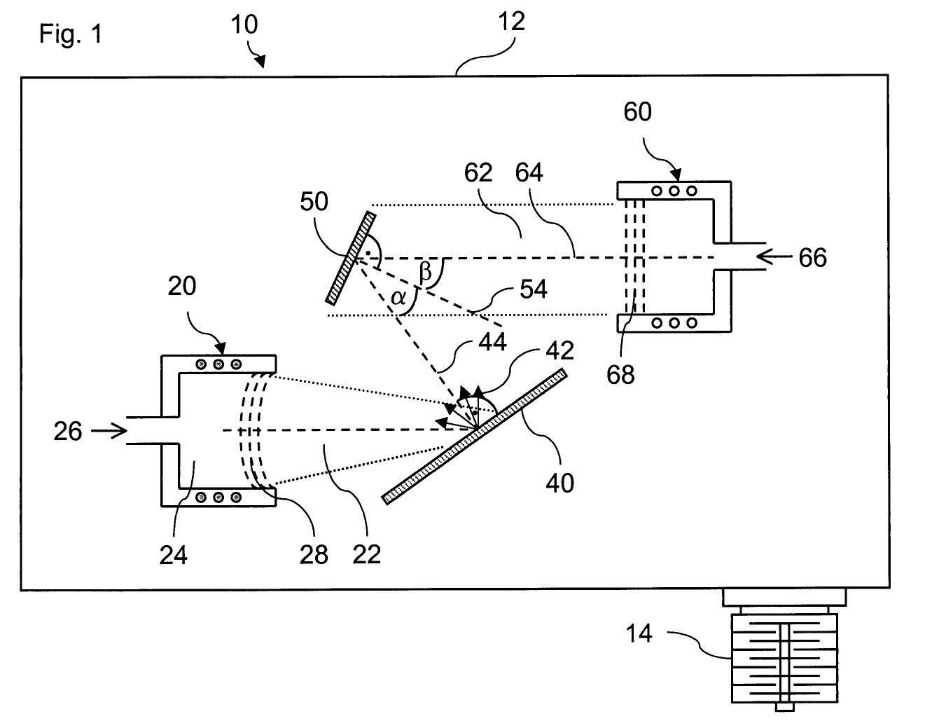

FIG. 1 schematically shows the setup of a deposition apparatus 10 for manufacturing of photo mask blanks by ion beam sputtering (IBS) or ion beam deposition (IBD) according to the invention. The apparatus 10 comprises a vacuum chamber 12 which is evacuated by a pump system 14.

A deposition particle source or more specifically ion deposition source 20 creates a first particle or ion beam 22. The deposition ion source 20 is a high frequency (HF) ion source, however, also other types of ion sources may be used. The sputter gas 24 is led into the deposition ion source 20 at inlet 26 and is ionized inside the deposition ion source 20 by atomic collisions with electrons, who are accelerated by an inductively coupled electromagnetic field. A curved three grid ion extraction assembly 28 is used to accelerate the primary ions, comprised in the first ion beam 22 and focus them towards the target 40.

The primary ions are extracted from the deposition ion source 20 and hit a target or sputter target 40, thereby causing cascades of atomic collisions and target atoms are bombed out. This process of sputtering or vaporizing the target is called the sputter process. The sputter target 40 is e.g. a molybdenum, silicon or chrome target, depending on the layer to be deposited. Preferably, the sputter process and the deposition of the layers take place in a suitable vacuum and are not supported by a reactive gas.

Several parameters can be adjusted to influence the momentum transfer function between the primary ions and the target atoms to optimize the laser quality. These method parameters are:

Mass of the primary ions,

Number of the primary ions per second (i.e. the ion current),

Energy of the first ion beam 22, defined by the acceleration voltage,

Incident angle of the first ion beam with respect to target normal line 44,

Density and purity of the target.

The momentum transfer to the target atoms is at largest, when the mass of the primary ions is equivalent to the mass of the target atoms. As rare gases are easy to handle, preferably argon or xenon is used as the sputter gas 24.

The statistical distribution of geometry and energy of the sputtered ions 42 leaving the target as consequence of the momentum transfer in the sputtering process is adjusted or controlled by at least one of the aforesaid method parameters.

In particular, the mean energy of the sputtered atoms, in this case chrome atoms, is adjusted or controlled by the energy and/or the incident angle of the first ion beam 22. The incident angle of the first ion beam 22 with respect to the target normal line 44 is adjusted by pivoting the target 40.

At least a portion of the sputtered ions 42 emerge from the target 40 in direction to substrate 50. The sputtered ions 42 hit the substrate 50 with an energy which is much higher than with conventional vapor deposition, deposition or growing highly stable and dense layers or films on the substrate 50.

The substrate 50 is rotatably mounted in a three axis rotation device. The mean incident angle α of the sputtered ions with respect to normal line 54 of the substrate 50 is adjusted by pivoting the substrate 50 around a first axis. By adjusting the incident angle α homogeneity, internal film structure and mechanical parameters, in particular film stress can be controlled and consequently improved.

Furthermore, the substrate 50 can be rotated perpendicular to the normal line 54 representing a second axis of rotation, to improve the homogeneity of the deposition.

The substrate is additionally rotatable or pivotable around a third axis, allowing to move the substrate out of the beam to allow for example cleaning of the substrate 50 immediately before deposition.

Furthermore, the apparatus 10 comprises an assist particle source or assist ion source 60. The operation principle is the same as the deposition source 20. A second particle or ion beam 62 is directed towards the substrate 50, e.g. for flattening, conditioning, doping and/or further treatment of the substrate 50 and/or films deposited on the substrate 50.

The second ion beam 62 is accelerated by a straight three grid extraction system 68.

The second ion beam 62 substantially covers the whole substrate 50 to obtain a homogenous ion distribution or treatment all over the substrate area. The second ion beam 62 is particularly used to

Dope the films with Oxygen, Nitrogen, Carbon and/or other ions,

Clean the substrate, for example with an Oxygen plasma, before the deposition,

Improve the interface quality of the films by flattening the films.

Depending on the particular treatment, the irradiation of the substrate 50 and/or films deposited on the substrate 50 with the second ion beam 62 can be before, simultaneously and/or after the deposition of films on the substrate 50. As can be seen in FIG. 1 the substrate 50 is tilted by an angle β with respect to the axis 64 of the second ion beam 62.

### EUV Photo Mask Blank (Example 1)

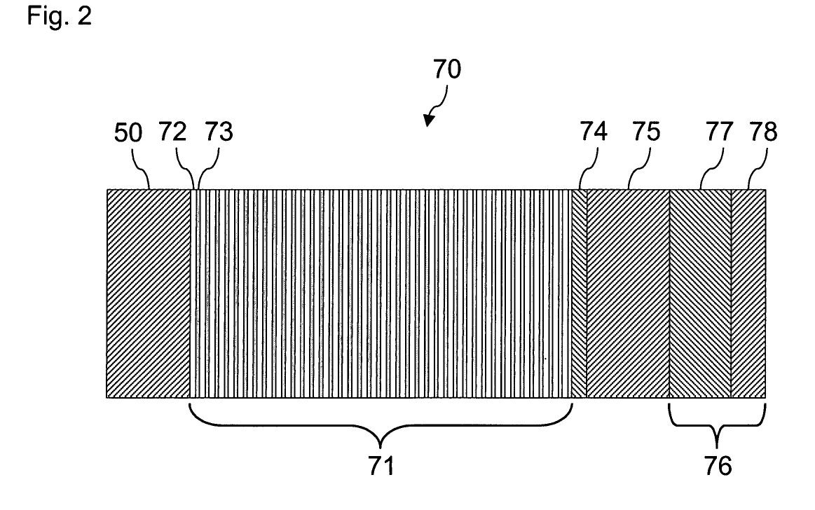

FIG. 2 shows a schematic drawing of an exemplary layer or film system of an EUV photo mask blank 70.

On the substrate 50 a high reflective multi-layer stack 71 comprising 40 bi-layers or alternating films of Molybdenum 72 and Silicon 73. For clearness, only the first bi-layer directly contacting the substrate 50 is denoted with reference signs 72 and 73 in the drawing. Each layer pair or film pair has a thickness of 6.8 nm and the fraction of

Molybdenum is 40%, resulting in a total thickness of 272 nm of the Mo/Si multi-layer stack 71. The multi-layer stack 71 represents an EUV mirror and is protected by a 11 nm Silicon capping layer or film 74 which is deposited on top of the multi-layer stack 71.

On top of the Silicon capping layer 74 an SiO₂ buffer layer 75 with a thickness of 60 nm is deposited. Further on top of the buffer layer 75 an absorber layer stack 76 comprising an anti-reflective chrome bi-layer system with a thickness of 70 nm is provided. The absorber layer stack 76 is consisting of two chrome layers 77 and 78.

For manufacturing a structured photo mask from the EUV photo mask blank 70, the absorber layer stack 76 is structured and partially removed by photo lithography. The buffer layer 75 allows a repair of the structured buffer layer without damage of the multi-layer stack mirror 71 underneath.

### Deposition Parameters for Example 1

The very low deposition rate of the method according to the invention allows very precise control of the layer thickness. This is highly advantageous, as particularly, the layers 72, 73 of the multi-layer stack mirror 71 are only a few nm thick. The layers 72, 73 can be deposited with a very controlled and reproducible and, therefore equal thickness of each bi-layer. The inventors have found, that with reduced deposition parameters as described in the following, the precision is further increased.

Argon is used as the sputter gas with 10 sccm and the energy of the primary Argon ions in the first ion beam 22 is 600 eV. The current of the first ion beam 22 is set to about 150 mA. To obtain a pure first ion beam beam, in the deposition source the background pressure is 2e-8 Torr and the partial pressure of Argon is set to 1e-4 Torr.

Molybdenum, silicon and chrome targets 40 are used for the deposition of the molybdenum films 72 Silicon and SiO₂ films 73, 74, 75 and chrome films 77, 78, respectively.

The SiO₂ buffer layer 75 is doped by the second ion beam 62 comprising oxygen ions with the assist ion source 60 using an oxygen flow of 15 sccm during and/or after the deposition of the buffer layer 75.

The top layer 78 of the absorber layer pair 77, 78 is doped by the second ion beam 62 using an oxygen flow of 8 sccm to reduce the reflection of the top chrome layer 78.

### Measurement Results of Example 1 Homogeneity

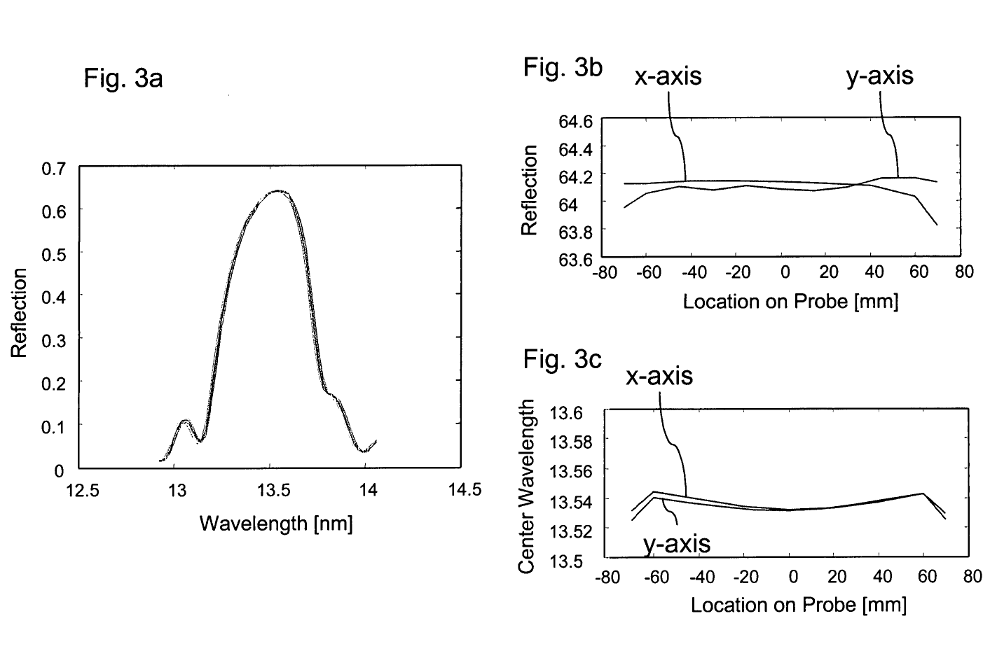

FIG. 3a to 3c show the results of normal incidence reflectivity measurements using syncrotron radiation at Physikalisch Technische Bundesanstalt (PTB) in Berlin, Germany. Two scans were made. One along the x-axis and one along the y-axis of the photo mask blank 70 being a square 6-inch plate. Each scan consists of 10 measurement points.

FIG. 3b shows the homogeneity of the reflection in a plot of the measured reflection as a function of the location on the 6-inch plate along the x-axis and y-axis.

FIG. 3c shows the homogeneity of peak reflection in a plot of the measured center wavelength as a function of the location on the 6-inch plate along the x-axis 88 and along the y-axis 84.

As can be seen from FIGS. 3b and 3c, respectively, the homogeneity of the peak reflection is better than ±0.2% and the homogeneity of the center wavelength is better than ±0.02 nm over the whole area of the photo mask blank 70.

FIG. 3a shows the results of the reflection measurements of all 20 measurement points of the two scans along the x-axis and y-axis together in one plot. The reflection as a function of the wavelength in nm is plotted and it can be seen that the homogeneity is that excellent, that the 20 curves are nearly not distinguishable in that plot.

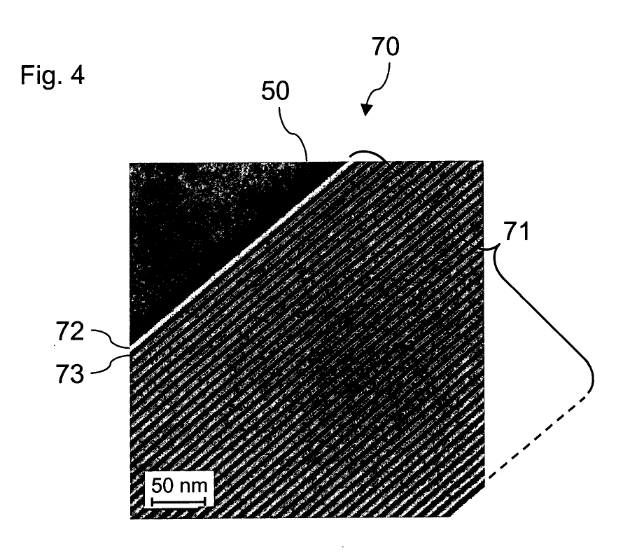

FIG. 4 shows a transmission electron microscopy image of a cross section of a portion of the photo mask blank 70. The substrate 50 and the multi-layer stack 71 are shown. All layers have very smooth surfaces and no systematic error is discernible. This demonstrates the excellent homogeneity and reproducibility of the layers or films deposited and treated by the inventive method.

### Interface Roughness

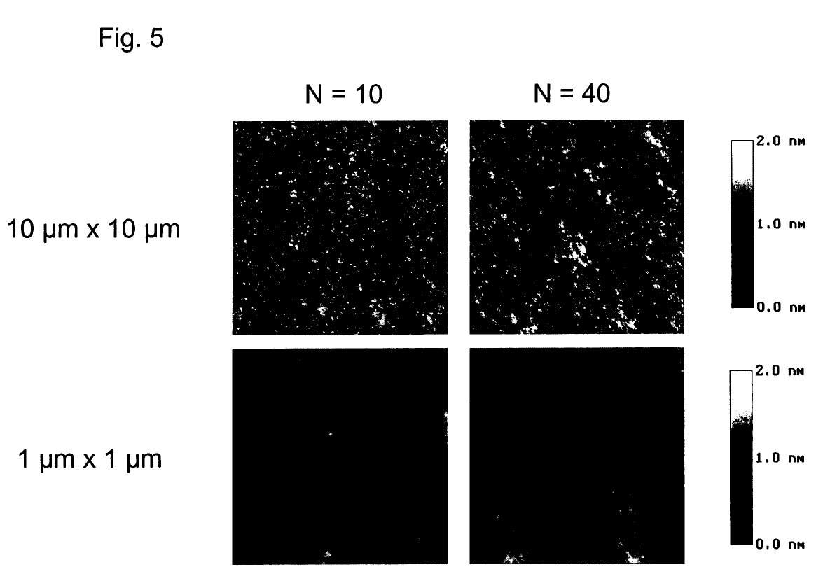

FIG. 5 shows surface measurements achieved by a raster atomic force microscope for two Mo/Si multi-layer stacks 70, 70′. The left column shows the results for a Mo/Si multi-layer stack 70′ with 10 bi-layers, whereas the right column shows the results for the Mo/Si multi-layer stack 70 with 40 bi-layers, as shown in FIGS. 2 and 4.

The upper row shows the results with a smaller magnification representing an area of 10 μm times 10 μm, whereas the lower row shows the results with a higher magnification representing an area of 1 μm times 1 μm.

From the two raster sizes it can be seen that there is no increased surface roughness for an increased number of bi-layers. Therefore the surface roughness does not increase during deposition with the inventive method. In fact, ion beam deposition according to the invention reproduces the roughness of the substrate across several layers, at least across 5, 10 or even 40 layers. At least one, most preferably all layers have a surface roughness of <5 nm rms, preferably <2 nm rms.

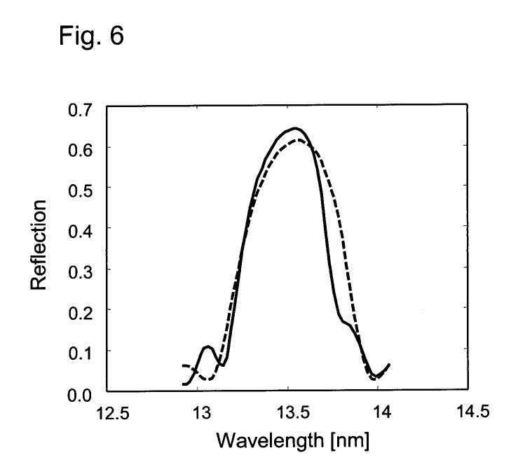

FIG. 6 shows, that treating the photo mask blank by the second ion beam 62 with the assist source 60 during the deposition process, the surface quality can be further increased. The solid curve is the reflection curve of a stack of 50 bi-layers without interface treatment or engineering. The dashed curve has only 30 bi-layers deposited with interface treatment or engineering in the form of flattening the layer interfaces. The increased surface quality allows to achieve the same value of reflection with a reduced number of layers, i.e. a reflection above 60% using only 30 bi-layers. Preferably, the treated photo mask blank 70 has a peak reflection rate which is at least 2%, 5%, 10%, 20% higher than the reflection rate of an untreated photo mask blank with the same number of layers.

### Binary Photo Mask Blank (Example 2)

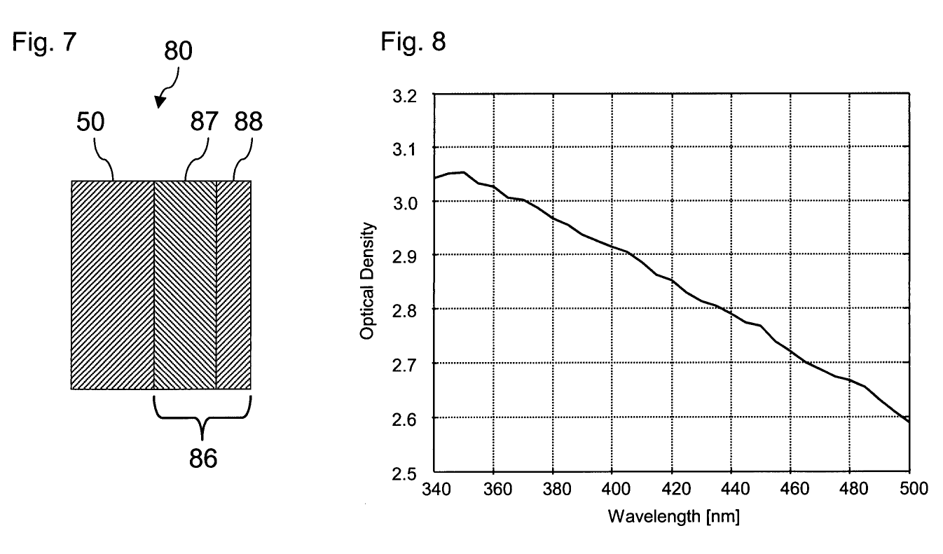

FIG. 7 shows a schematic cross section of a binary photo mask blank 80. The binary photo mask blank 80 comprises an absorber layer stack 86 of at least two layers 87, 88 deposited on the substrate 50.

The first layer 87 is e.g. a chrome layer and achieves the required optical density, while the second layer 88 is e.g. a chrome-oxide layer providing an antireflective coating. In this example the first layer has a thickness of 48 nm and the second layer a thickness of 22 nm.

### Deposition Parameters for Example 2

The binary photo mask blank 80 does not include layers as thin as the bi-layers 72, 73 of the afore-described EUV photo mask blank 70. Therefore, relatively high deposition parameters as follows may be used as follows:

Primary Atoms: Argon 10 sccm

Primary Energy: 1300 eV

Primary Current: 350 mA

Background Pressure: 2e-8 Torr

Deposition Pressure: 1e-4 Torr

The sputter target 40 for both layers is a chrome target. The second or top layer 88 of the absorber layer stack 86 is doped by the second ion beam 62 comprising oxygen ions using an oxygen gas flow 66 of 8 sccm to reduce the reflection.

### Measurement Results of Example 2

FIG. 8 shows the measured optical density as a function of the wavelength for the binary photo mask blank 80. The layer stack or system 86 is designed to achieve an optical density of at least 3 at in the area of the design wavelength, which is in this example 365 nm.

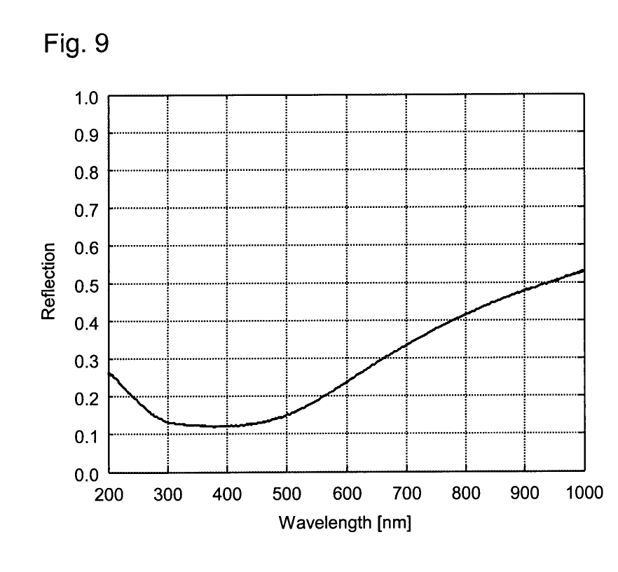

FIG. 9 shows the measured reflection curve as a function of wavelength. The layer stack or system 86 is designed to fulfill a quarter wavelength condition at the design wavelength of 365 nm. Thickness and oxygen content of the antireflection layer 88 are adjusted to achieve a minimum of the reflection of ≦12% at the design wavelength.

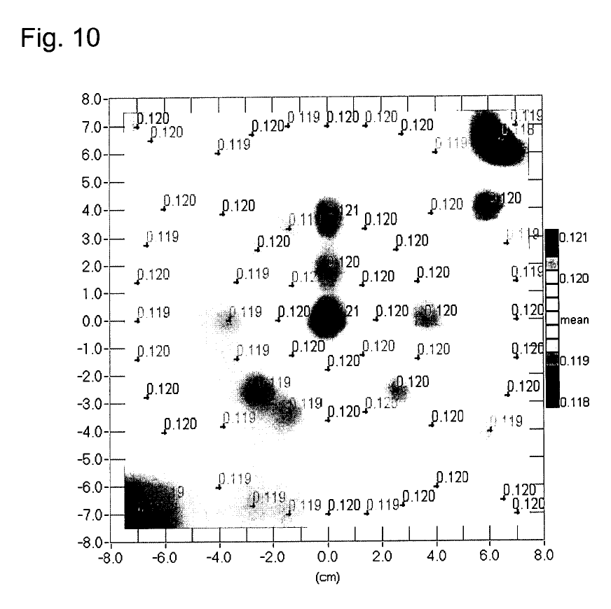

FIG. 10 shows a contour plot of the reflection at 365 nm measured in two dimensions over the surface of the 6-inch photo mask blank 80. A homogeneity of the reflection better than ±0.2% over the photo mask blank 80 is advantageously achieved.

Phase Shifting Photo Mask Blanks (Examples 3, 4, 5)

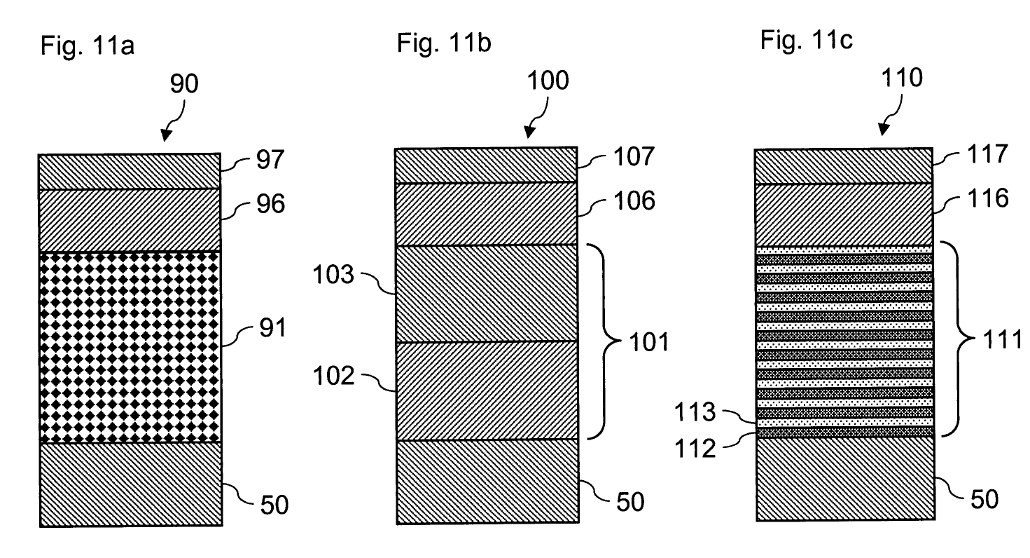

FIGS. 11a to 11c show cross sections of three types of phase shifting photo mask blanks 90, 100, 110. The photo mask blanks 90, 100, 110 comprise a phase shifting layer structure 91, 101, 111, respectively, which causes a phase shift of 180° and have a transmission of about 6%. The phase shifting layer structure is either a single layer 91 made of a homogenous or composite material, a bi-layer 101 or a multi-layer 111. The latter one allows enhanced control because of the increased number of free parameters.

FIG. 11a shows a phase shifting photo mask blank 90 with a composite phase shifting layer 91 deposited directly on an upper surface of the transparent substrate 50.

FIG. 11b shows a phase shifting photo mask blank 100 with a bi-layer phase shifting structure 101 deposited in contact with an upper surface of the substrate 50. The bi-layer structure 101 comprise a first and second layer 102, 103.

FIG. 11c shows a phase shifting photo mask blank 90 with a multi-layer phase shifting structure 111 grown on the substrate 50. The multi-layer structure 111 consists of ten bi-layers 102, 103.

The phase shifting structure 91, 101, 111 of each of the phase shifting photo mask blanks 90, 100, 110 has a thickness of 140 nm. Further an anti-reflective chrome layer pair 96, 97; 106, 107; 116, 117 with a thickness of 70 nm has been grown on the respective phase shifting layer structure 91, 101, 111.

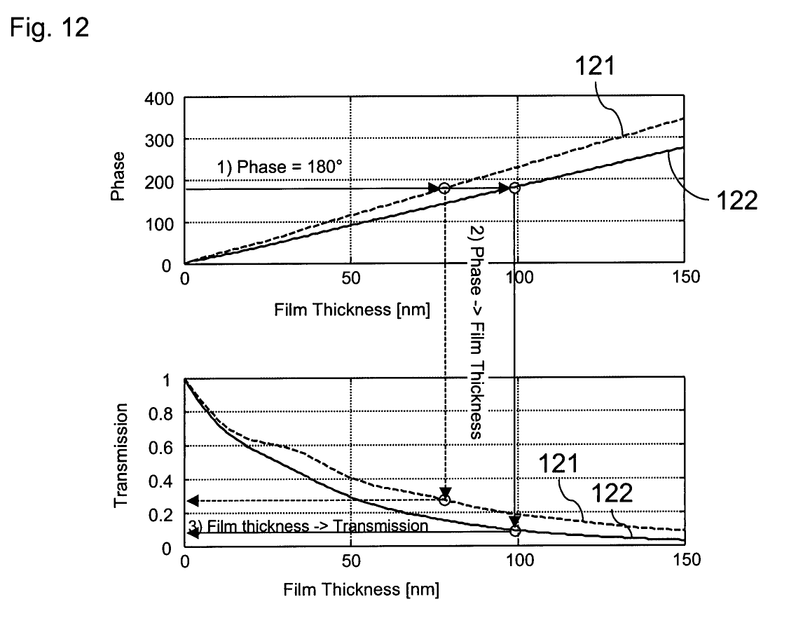

FIG. 12 shows a calculation of a single layer phase shift according to the example shown in FIG. 11a. It can been seen in FIG. 12, that the desired phase shift of 180° defines the film thickness and, therewith, the transmission. The transmission can only be influenced by varying the optical constants of the material. Therefore, there is no further degree of freedom for the structural design.

In FIG. 12 two plots 121, 122 for two materials with different optical constants are shown by the solid and dashed line, respectively. As can be extracted from the plots, the resulting film thickness for those examples is about 80 nm and about 100 nm and the resulting transmission is about 0.275 and about 0.1, respectively.

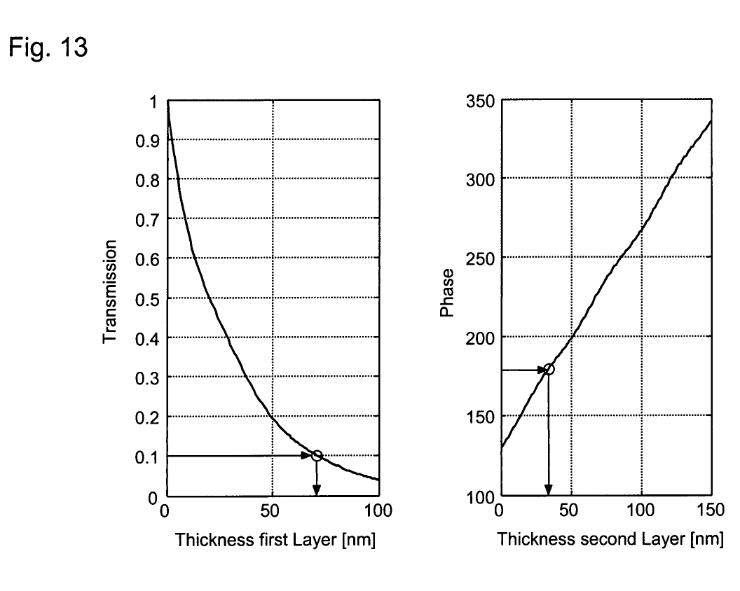

FIG. 13 shows a calculation of a bi-layer phase shift according to the example shown in FIG. 11b. Here the film thickness of the second layer 103 is an additional free parameter to the thickness of the first layer 102.

It can been seen from the left plot in FIG. 13, that the thickness of the first layer 102, which is a high absorbing layer can be adjusted to the desired transmission, which is in this example 0.1, achieved with a thickness of about 70 nm.

The thickness of the second layer 103 which is grown of a low absorbing material is then adjusted to achieve a phase shift of 180°. As can be seen from the right plot in FIG. 13 the thickness of the second layer is chosen to about 30 nm.

Two materials, i.e. a material with a high absorption coefficient to adjust the target transmission for the first layer 102 and a material with a low absorbing coefficient for the second layer 103 to adjust the phase shift to 180° are used. In this example SiN for the absorbing first layer 102 and SiO₂ for the phase shifting second layer 103 are chosen.

### Deposition Parameters for (Example 3)

Since the layers are relatively thick, high deposition parameters are chosen as follows:

Primary Atoms: Argon 10 sccm

Primary Energy: 1300 V

Primary Current: 350 mA

Background Pressure: 2e-8 Torr

Deposition Pressure: 1e-4 Torr

Silicon and Chrome targets are used as the sputter target 40.

The SiN layer 102 is doped with Nitrogen using a flow of 22 sccm and the SiO₂ layer 103 is doped with Oxygen using a flow of 15 sccm. The Nitrogen is ionized in the assist source 60 and accelerated towards the substrate 50 using an acceleration voltage of 100 V. The chrome layer is the same as in the binary example shown in FIG. 7.

### Measurement Results of Example 3

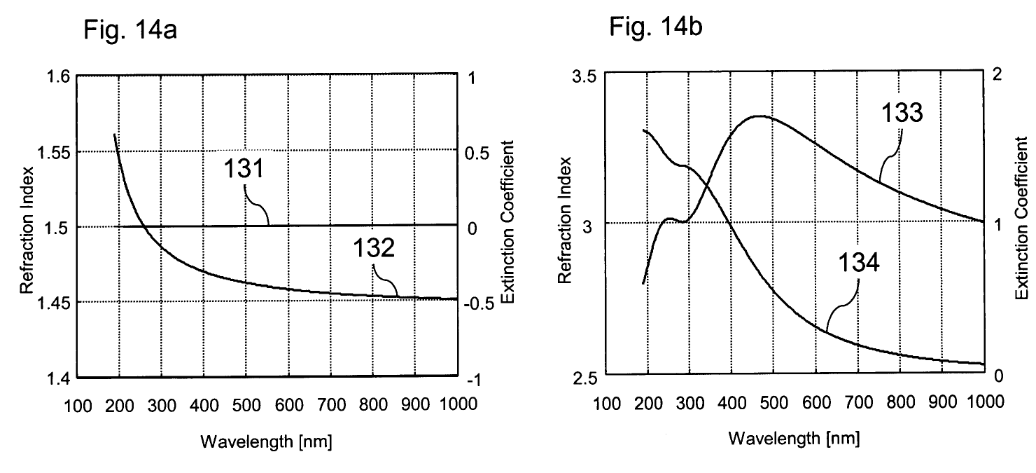

FIGS. 14a and 14b show the measured dispersion of the optical constants of the SiN and SiO₂ layers 102, 103. An N&K photo spectrometer was used for the measurement.

FIG. 14a shows a plot of the refraction index 131 and the extinction index 132 of the SiO₂ layer 103 and FIG. 14b shows a plot of the refraction index 133 and the extinction index 134 of the SiN layer 102, each as a function of the light wavelength.

The optical constants for 193 nm are found to be:

| | Refraction index | Extinction |
|---|---|---|
| | @ 193 nm | coefficient @ 193 nm |
| SiN | 2.81 | 1.61 |
| SiO2 | 1.56 | 0 |

Using these dispersion data an examplary embodiment for the bi-layer phase shifting photo mask blank 100 is designed with the following parameters:

Thickness of SiN: 27 nm

Thickness of SiO₂: 92 nm

Relative Transmission: 6.2%

Phase shift: 180°.

Furthermore a multi-layer phase shifting photo mask blank 110 was designed with the following parameters:

Thickness of every SiN layer: 1.6 nm

Thickness of every SiO2 layer: 12.7 nm

Number of bi-layers: 10

Relative Transmission: 6.1%

Phase shift: 180°.

For both phase shifting photo mask blanks 100 and 110 the phase shift was not measured directly but was calculated using the measured dispersion data and the measured film thickness. Grazing incidence X-Ray reflectometry was used to determine the film thickness with high precision.

It is clear to those skilled in the art that all features of the invention, of the preferred embodiments and cited in the patent claims can be combined with each other and that many details of the described examples can be altered without leaving the scope of the invention.

1. A method for manufacturing of a photo mask blank, in particular of a binary photo mask blank, a phase shifting photo mask blank or an extreme ultra violet photo mask blank, comprising the steps of:
providing a substrate and a target in a vacuum chamber,
providing a first particle beam,
sputtering said target by irradiating with said first particle beam,
depositing at least a first layer of a first material on said substrate by said sputtering of said target.

2. The method of claim 1, wherein
said first particle beam is directed onto said target and sputtered particles emerge from said target in direction to said substrate.

3. The method of claim 1, wherein
at least a second layer of a second material is deposited on said photo mask blank by sputtering of said target.

4. The method of claim 1, wherein
said target defines a target normal line and said first particle beam hits said target under an angle to said target normal line.

5. The method of claim 1, wherein
said substrate defines a substrate normal line and sputtered particles from said target hit said photo mask blank under an angle to said substrate normal line.

6. The method of claim 1 wherein the rate of depositing of said first layer is between 0.01 and 5 nm/sec.

7. The method of claim 1, wherein
said photo mask blank is irradiated by a second particle beam.

8. The method of claim 7, wherein
said substrate defines a substrate normal line and said second particle beam hits said photo mask blank under an angle to said substrate normal line.

9. The method of claim 7, wherein
at least one of said first and second particle beam comprises an ion beam.

10. The method of claim 7, wherein
at least one of said first and second particle beam comprises an ion beam, which is accelerated and focused by an electromagnetic field.

11. The method of claim 7 wherein said first and second particle beams are separately controlled for independently depositing layers by said first particle beam and treating at least one of said substrate and said layers by said second particle beam.

12. The method of claim 7, wherein
said first and second particle beams comprise different particles.

13. The method of claim 7, wherein
said first and second particle beams have different particle energies.

14. The method of claim 7, wherein
a surface of said substrate is conditioned by irradiating with said second particle beam.

15. The method of claim 7, wherein
a surface of said substrate is cleaned from impurities by irradiating with said second particle beam before said deposition of said first layer.

16. The method of claim 15, wherein
at least one reactive gas is provided in said vacuum chamber at a predetermined pressure and said cleaning is enhanced by said at least one reactive gas.

17. The method of claim 16, wherein
said at least one reactive gas comprises oxygen.

18. The method of claim 7, wherein
at least one of the layers is doped by irradiating with said second particle beam.

19. The method of claim 18, wherein
a plurality of layers is deposited on said photo mask blank and different layers are differently doped.

20. The method of claim 18,
wherein at least one of the following parameters:
optical density,
etch time,
adhesion and
reflectance
of at least one of the layers is controlled by said doping.

21. The method of claim 7,
wherein a surface of at least one of the layers is flattened by irradiating with said second particle beam after the deposition of said at least one layer.

22. The method of claim 7 wherein further layers are deposited on said photo mask blank and interface roughness between said layers is reduced by irradiating with said second particle beam.

23. The method of claim 7 wherein reflectance of a surface of a reflecting layer is increased by irradiating with said second particle beam.

24. A method for manufacturing of a photo mask blank, in particular of a binary photo mask blank, a phase shifting photo mask blank or an extreme ultra violet photo mask blank, comprising the steps of:
providing a substrate and a sputter target in a vacuum chamber,
providing a deposition particle source and an assist particle source,
providing a first and second particle beam by means of said deposition and assist particle source, respectively,
sputtering said target by irradiating with said first particle beam, wherein said first particle beam is directed from said deposition particle source onto said target and sputtered particles emerge from said target in direction to said substrate,
depositing (growing) at least a first layer of a first material on said substrate by said sputtering of said target.
depositing (growing) at least a second layer of a second material on said first layer by sputtering of said target,
irradiating said photo mask blank with said second particle beam for treating said substrate or at least one of said layers.

25. A method for manufacturing of a photo mask blank, in particular of a binary photo mask blank, a phase shifting photo mask blank or an extreme ultra violet photo mask blank, comprising the steps of:
providing a substrate in a vacuum chamber,
growing a layer of a first material on said substrate,
wherein said step of growing said layer is performed by ion beam deposition (IBD).

26. The photo mask blank, in particular being a binary photo mask blank, an extreme ultra violet photo mask blank or a phase shifting photo mask blank, obtainable by the method of claim 1, 24 or 25.

27. A mask blank, in particular a binary photo mask blank, a phase shifting photo mask blank or an extreme ultra violet photo mask blank, comprising
a substrate and
one or more layers being deposited on said substrate by ion beam deposition.

28. The mask blank of claim 27, wherein
said mask blank is characterized by being treated by irradiating with a second particle beam.

29. The mask blank of claim 27, wherein
at least one of said layers has a grain size of 0 nm to 10 nm.

30. The mask blank of claim 27, wherein
at least one of said layers has a surface roughness of lower than 5 nm rms.

31. The mask blank of claim 27 further comprising a light reducing (or absorber) layer.

32. The mask blank of claim 27 further comprising an anti-reflective layer.

33. A photo mask manufactured (by a lithography method) of the mask blank of claim 27.

34. An apparatus for manufacturing of a mask blank, in particular of a binary photo mask blank, a phase shifting photo mask blank or an extreme ultra violet photo mask blank, comprising
a vacuum chamber suitable for evacuation and in which a substrate and a target are disposable,
a deposition particle source for providing a first particle beam which is directable towards said target for sputtering of said target and depositing at least a first layer on said substrate and
an assist particle source for providing a second particle beam which is directable towards said substrate for treating of said substrate.

35. The apparatus of claim 34, wherein
at least one of said deposition particle source and said assist particle source provide an ion beam.

36. The apparatus of claim 34, wherein
said deposition particle source provides a first ion beam and said apparatus comprises means for providing an electromagnetic field for accelerating and focusing said first ion beam on its way to said target.

37. The apparatus of claim 34, wherein
said deposition and assist particle source are separately controllable.

38. The apparatus of claim 34, wherein
said deposition particle source and said assist particle source are suitable to provide beams of at least one of
different directions,
different particles and
different particle energies.
